(19) United States
(12) Patent Application Publication
(10) Pub. No.: US 2007/0069352 A1
(43) Pub. Date: Mar. 29, 2007

(54) Bumpless chip package and fabricating process thereof

(76) Inventors: Kwun-Yao Ho, Hsin-Tien City (TW); Moriss Kung, Hsin-Tien City (TW)

Correspondence Address: J.C. Patents, Inc., Suite 250, 4 Venture, Irvine, CA, 92618, US

(21) Appl. No.: 11/360,216

(22) Filed: Feb. 22, 2006

(30) Foreign Application Priority Data
Sep. 27, 2005 (TW) 94133509

(51) Int. Cl. H01L 23/02

(52) U.S. Cl. 257/678

(57) ABSTRACT

A bumpless chip package comprising a supporting component, a chip, a metal-filled layer and an interconnection structure is provided. The supporting component has a supporting surface and a cavity. The chip is disposed within the cavity and has a plurality of chip pads formed on an active surface of the chip, wherein the active surface is upward. The metal-filled layer is filled in a space formed between the chip and the cavity. The interconnection structure is formed above the active surface of the chip and the supporting surface of the supporting component, and has an inner circuit and a plurality of contact pads. The contact pads are formed on a contact surface of the interconnection structure. At least one of the chip pads is electrically connected with at least one of the contact pads by the inner circuit.

### CROSS-REFERENCE TO RELATED APPLICATION

This application claims the priority benefit of Taiwan application serial no. 94133509, filed on Sep. 27, 2005. All disclosure of the Taiwan application is incorporated herein by reference.

### BACKGROUND OF THE INVENTION

1. Field of Invention

The present invention relates to a chip package and the fabricating process thereof, and more particularly to a bumpless chip package and the fabricating process thereof.

2. Description of Related Art

With the constant improvement of electronic technologies every day, in order to meet various demands on electronic components such as high-speed processing, multi-function, integration, miniature, light weight and low prices, the development of chip package technology also tends to move towards miniaturization and high density. Conventional ball grid array (BGA) package technology often employs a package substrate as the carrier of the integrated circuit (IC) chip, electrically connects the chip to the top surface of the package substrate by the electrical connection techniques such as flip chip bonding or wire bonding, and then disposes a plurality of solder balls on the bottom surface of the package substrate in area array. Therefore, the chip can be electrically connected to the electronic device of the next level, for example, the Printed Circuit Board, via the inner circuit of the package substrate and a plurality of solder balls on the bottom thereof.

However, the conventional BGA package technology has to use the package substrate of high layout density, in combination with the electrical connection techniques such as flip chip bonding or wire bonding, thus resulting in a rather long signal transmission path. Therefore, a chip package technology of bumpless build-up layer (BBUL) has been developed recently, wherein the fabricating process of flip chip bonding or wire bonding is omitted, and a multi-layered interconnection structure is made directly on the chip, and the electrical contacts such as solder balls or pins are fabricated on the multi-layered interconnection structure in area array to be electrically connected to the electronic device of the next level.

Referring to FIG. 1, a cross-sectional view of a conventional bumpless chip package is illustrated. The conventional bumpless chip package 100 comprises a heat spreader 110, a chip 120, a thermal-conductive adhesion layer 130, an interconnection structure 140 and a plurality of solder balls 150. The heat spreader 110 has a supporting surface 112 and a cavity 114. The chip 120 is disposed within the cavity 114 and has a plurality of chip pads 122 formed on an active surface 124 of the chip 120, wherein the active surface 124 is exposed to the outside of the cavity 114. It can be known from FIG. 1 that the chip 120 is adhered within the cavity 114 by the thermal-conductive adhesion layer 130.

The interconnection structure 140 is formed on the active surface 124 of the chip 120 and the supporting surface 112 of the heat spreader 110, wherein the interconnection structure 140 has an inner circuit 142 and a plurality of contact pads 144. The contact pads 144 are formed on a contact surface 146 of the interconnection structure 140. At least one of the chip pads 122 is electrically connected with at least one of the contact pads 144 by the inner circuit 142.

Additionally, the interconnection structure 140 comprises a plurality of dielectric layers 148, a plurality of conductive vias 142a and a plurality of circuit layers 142b. The conductive vias 142a and the circuit layers 142b form the inner circuit 142 described above. In particular, at least one of the conductive vias 142a is electrically connected with at least one of the chip pads 122. The conductive vias 142a run through the dielectric layers 148 respectively, and the dielectric layers 148 and the circuit layers 142b are formed alternately with each other. It can be known from FIG. 1 that two of the circuit layers 142b are electrically connected by at least one conductive via 142a. The solder balls 150 are disposed respectively on the contact pads 144 to be electrically connected to the electronic device (not shown) of the next level. It should be noted that, when or before the interconnection structure 140 is formed, part of the dielectric layer 148 is filled within the space S formed between the sides of the chip 120 and the sidewalls of the cavity 114 of the heat spreader 110 to stabilize the relative position of the chip 120 and the cavity 114.

However, since the thermal conductivity of the dielectric material located between the chip 120 and the cavity 114 is poor, the heat caused during the operation of the chip 120 is conducted to the heat spreader 110 mainly by the thermal-conductive adhesion layer 130 located at the back surface of the chip 120, thus the overall heat dissipation of the conventional bumpless chip package 100 is poor. Moreover, it is not easy to fill the dielectric material described above into space S between the sides of the chip 120 and the side walls of the cavity 114. Furthermore, since the coefficient of thermal expansion (CTE) of the dielectric material described above does not match with the coefficients of thermal expansion of the heat spreader 110 and the chip 120, the thermal stress may remain in the dielectric material. As described above, it is indeed necessary to improve the conventional bumpless chip package 100.

### SUMMARY OF THE INVENTION

The present invention provides a bumpless chip package comprising a supporting component, a chip, a metal-filled layer and an interconnection structure. The supporting component has a supporting surface and a cavity. The chip is disposed within the cavity, and the chip has a plurality of chip pads formed on an active surface of the chip, wherein the active surface is upward. Moreover, the metal-filled layer is filled in a space formed between the chip and the cavity. Additionally, the interconnection structure is formed above the active surface of the chip and the supporting surface of the supporting component and has an inner circuit and a plurality of contact pads. The contact pads are formed on a contact surface of the interconnection structure. At least one of the chip pads is electrically connected with at least one of the contact pads by the inner circuit.

The present invention further provides a fabricating process of the bumpless chip package. A supporting component having a supporting surface and a cavity is provided. A chip having a plurality of chip pads formed on an active surface of the chip is provided. The chip is disposed within the cavity, wherein the active surface is upward. A metal-filled layer in a space formed between the chip and the cavity is formed. An interconnection structure above the active surface of the chip and the supporting surface of the supporting component is formed. The interconnection structure has an inner circuit and a plurality of contact pads. The contact pads are formed on the contact surface of the interconnection structure. At least one of the chip pads is electrically connected with at least one of the contact pads by the inner circuit.

In order to make the aforementioned features and advantages of the present invention more comprehensible, preferred embodiments accompanied with appended drawings are described in detail below.

### BRIEF DESCRIPTION OF THE DRAWINGS

FIG. 1 is a cross-sectional view of a conventional bumpless chip package;

FIGS. 2A-2D are the cross-sectional views of the fabricating process of bumpless chip package according to an embodiment of the present invention;

FIG. 3 is a top view of the opening and the conductive part of FIG. 2C; and

FIG. 4 is a cross-sectional view of the bumpless chip package according to another embodiment of the present invention.

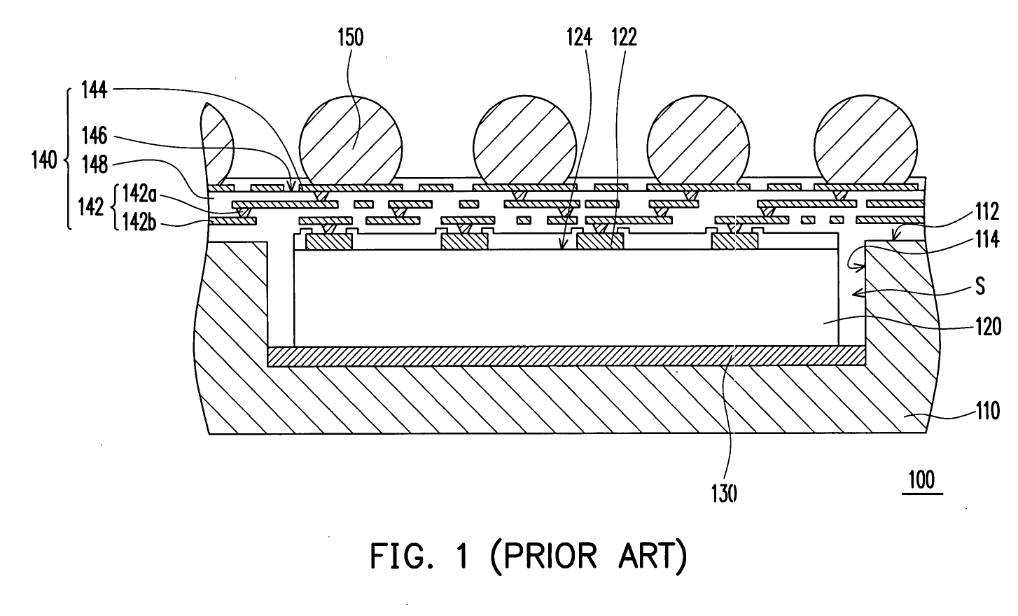

### DESCRIPTION OF EMBODIMENTS

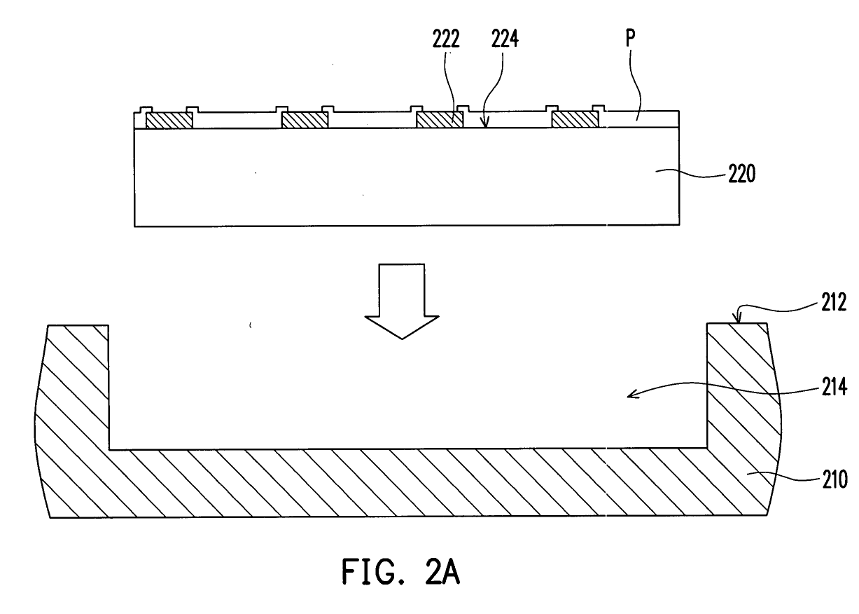

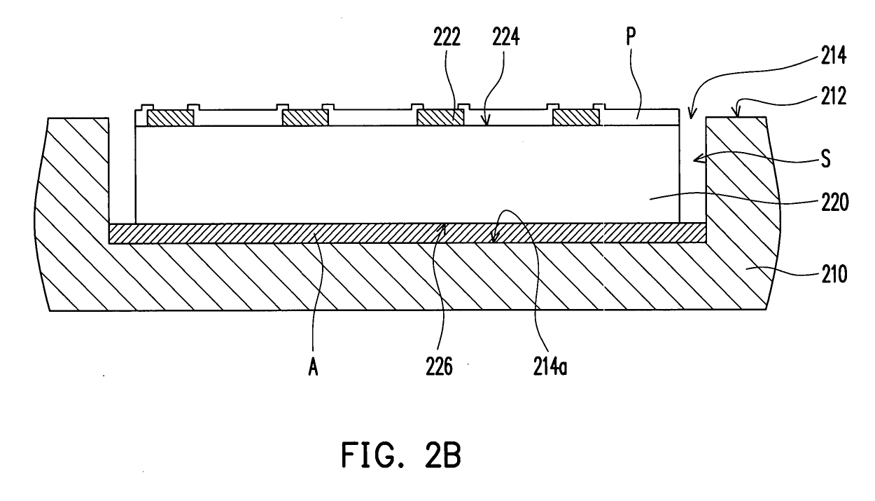

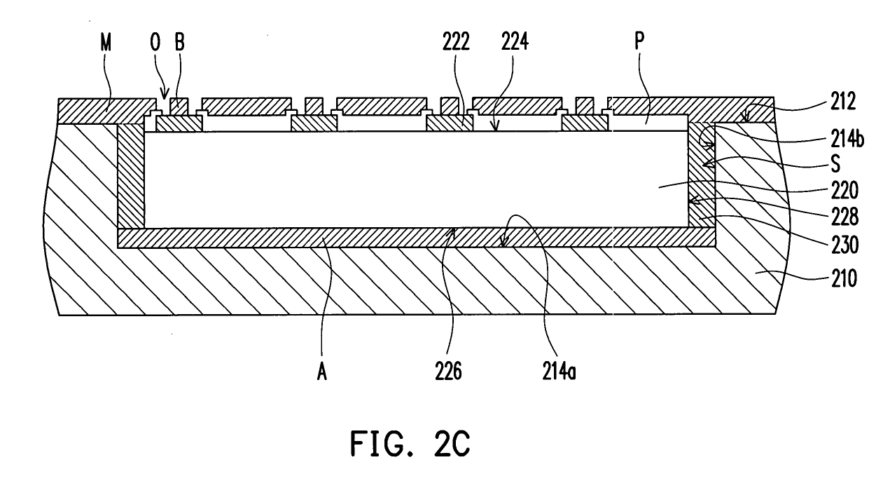

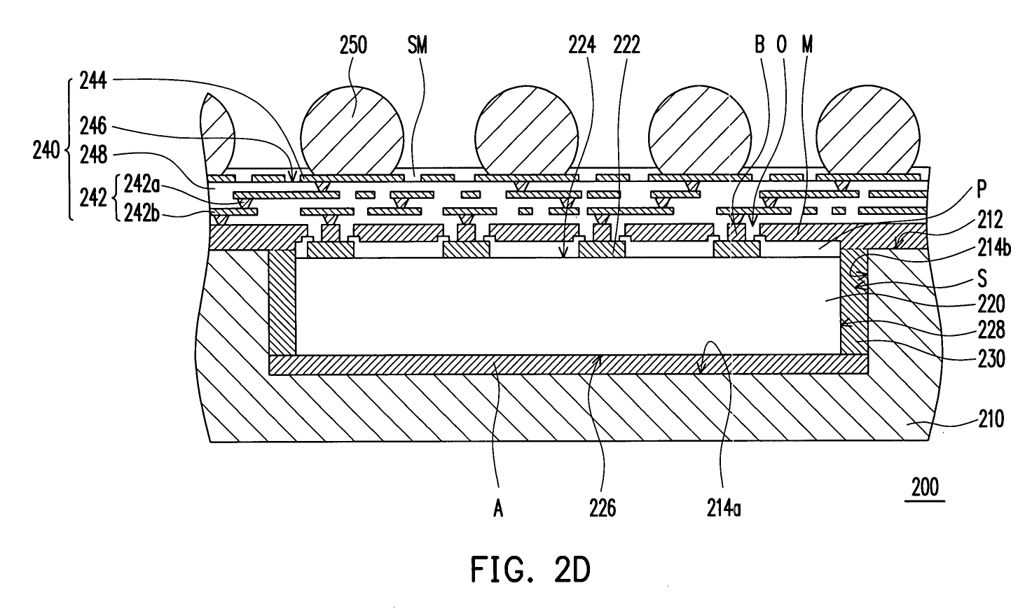

FIGS. 2A-2D are the cross-sectional views of the fabricating process of bumpless chip package according to an embodiment of the present invention. Referring to FIG. 2A, first, a supporting component 210 is provided. The supporting component 210 has a supporting surface 212 and a cavity 214. In the embodiment, the supporting component 210 is, for example, a heat spreader, and the material thereof is, for example, metal.

Then, a chip 220 is provided. The chip 220 has a plurality of chip pads 222 which are formed on an active surface 224 of the chip 220. In the embodiment, the chip 220 further has a protection layer P, which is formed on the active surface 224 and exposes each of the chip pads 222. The protection layer P is used to protect the inner circuit (not shown in FIG. 2A) of the chip 220, so as to prevent the inner circuit of the chip 220 from the destruction by the external moisture, temperature or external forces.

Then, referring to FIGS. 2A and 2B, the chip 220 is disposed within the cavity 214, and let the active surface 224 face upward. In the embodiment, a back surface 226 of the chip 220 opposite to the active surface 224 is correspondingly adhered onto a bottom surface 214a of the cavity 214 by, for example, a thermal-conductive adhesion layer A. The material of the thermal-conductive adhesion layer A may be solder, alloy metal or thermal-conductive paste.

Further, referring to FIGS. 2B and 2C, a space S is formed between at least one side 228 of the chip 220 and at least one corresponding side wall 214b of the cavity 214, wherein a metal-filled layer 230 is formed in the space S. The metal-filled layer 230 can be formed by depositing the metal particles into the space S to fill up the space S through, for example, electrolytic plating, sputtering or metal deposition.

In the embodiment, the metal-filled layer 230 uses metal material, for example, elemental metal or alloy metal, which has excellent characteristics of thermal conductivity. Therefore the thermal conductive efficiency between the chip 220 and the supporting component 210 can be increased. Furthermore, the coefficient of thermal expansion of the supporting component 210 can be set the same as or similar to the coefficient of expansion of the metal-filled layer 230, therefore the mismatch between the thermal expansion of the chip 220 and the supporting component 210 can be reduced so as to decrease the remaining of the thermal stress.

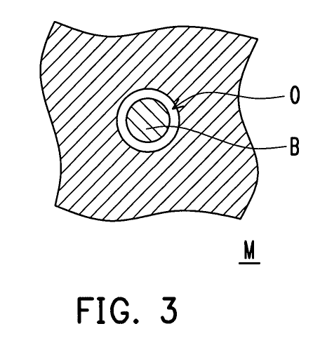

Referring to FIG. 2C, a patterned conductive layer M can be formed on the active surface 224 of the chip 220 and the supporting surface 212 of the supporting component 210 to expose part of each of the chip pads 222. The patterned metal layer M, for example, has a plurality of openings O and a plurality of conductive parts B, wherein each of the conductive parts B is formed on a corresponding one of the chip pads 222, and is located within a corresponding one of the openings O. Each of the openings O exposes a corresponding one of the corresponding chip pads 222, and is used for the electronic insulation from a corresponding one of the corresponding conductive parts B. Refer to FIGS. 3 and 2C, FIG. 3 is a top view of the opening and the conductive part of FIG. 2C. In the embodiment, the openings O, for example, are cylinder shaped openings, while the conductive parts B, for example, are of column shape, and both of the opening O and the conductive B together, for example, form a ring trench.

The formation of the patterned metal layer M as described above may include a first step of forming a metal layer (not shown in FIG. 2C) on the active surface 224 of chip 220 and the supporting surface 212 of the supporting component 210 by electroplating, and a second step of patterning the metal layer to form the patterned metal layer M. It should be noted that, the material of the patterned metal layer M and the metal-filled layer 230 may be the same as what is used in the electroplating process, so that electroplating can be conducted successively right after the formation of the metal-filled layer 230, so as to form the metal layer described above.

Referring to FIG. 2D, an interconnection structure 240 is formed above the active surface 224 of the chip 220 and the supporting surface 212 of the supporting component 210. The interconnection structure 240 has an inner circuit 242 and a plurality of contact pads 244. The contact pads 244 are formed on a contact surface 246 of the interconnection structure 240, and at least one of the chip pads 222 is electrically connected with at least one of the contact pads 244 by the inner circuit 242.

The interconnection structure 240 described above, for example, is formed on the patterned metal layer M by a build-up process. In particular, the dielectric layer 248, at least one conductive via 242a running through the dielectric layer 248, and the circuit layers 242b electrically connected with the conductive vias 242a are sequentially formed on the patterned metal layer M. The interconnection structure 240 can be formed by conducting the above steps once or more times according to the requirements of design. In the embodiment, the interconnection structure 240, for example, comprises a plurality of dielectric layers 248, a plurality of conductive vias 242a and a plurality of circuit layers 242b, wherein the conductive vias 242a and the circuit layers 242b form the inner circuit 242. It can be known from FIG. 2D that at least one of the conductive vias 242a is electrically connected with at least one of the chip pads 222, and the circuit layer 242b and the dielectric layer 248 are formed alternately, wherein the two circuit layers 242b are electrically connected with each other by at least one of the conductive vias 242a. It should be noted herein that since the contact pads 244 and the outermost layer of the circuit layers 242b are formed in a same patterned conductive layer. In other words, the contact pads 244 and the outermost layer of the circuit layers 242b can be formed through the same fabricating process to form a patterned metal layer.

Referring to FIG. 2D, a solder mask layer SM can be formed on the contact surface 246 of the interconnection structure 240, and each of the contact pads 244 is exposed. The solder mask layer SM is used to protect the inner circuit 242 of the interconnection structure 240 in order to prevent the inner circuit 242 from the destruction by external moisture, temperature or external forces. Finally, electrical contacts 250 can be respectively formed on the contact pads 244 to be electrically connected to the electronic device of the next level (not shown in FIG. 2D). In the embodiment, the electrical contacts 250, for example, are conductive balls, but also can be conductive pins or conductive columns. The bumpless chip package 200 of the embodiment is formed through the above steps.

It should be mentioned that the contact pads 244 can be used for the signal I/O interfaces of land grid array (LGA) type, if a plurality of electrical contacts 250 have not been respectively disposed on the contact pads 244. If the electrical contacts 250 are conductive balls, they can be used to provide the signal I/O interfaces of ball grid array (BGA) type. If the electrical contacts 250 are conductive pins, they can be used to provide the signal I/O interfaces of pin grid array (PGA) type. If the electrical contacts 250 are conductive columns, they can be used to provide the signal I/O interfaces of column grid array (CGA) type.

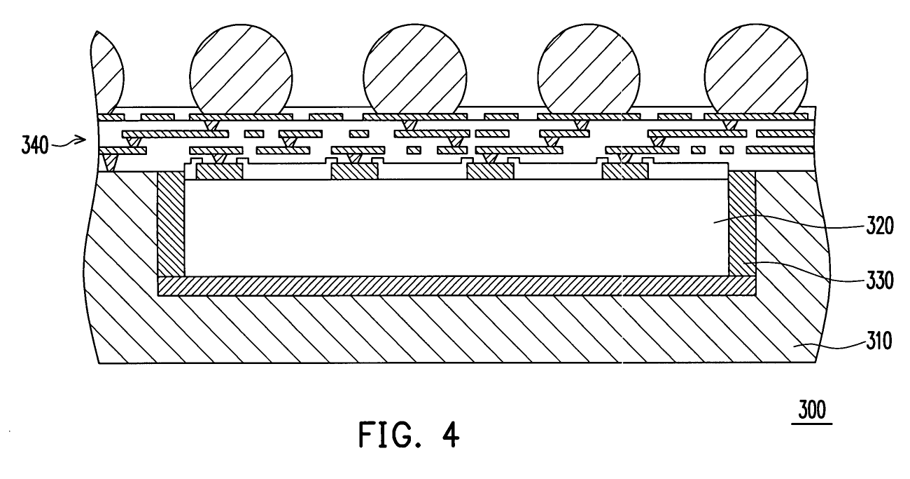

Referring to FIG. 4, a cross-sectional view of the bumpless chip package according to another embodiment of the present invention is illustrated. The difference between this embodiment of FIG. 4 and the above embodiment of FIG. 2D is that the bumpless chip package 300 does not comprise the patterned metal layer M (see FIG. 2D). Therefore, in the fabricating process, the patterned metal layer M according to FIG. 2D can be removed after its formation or the aforementioned steps of forming the patterned metal layer M can be just omitted. It can be known from FIG. 4 that the interconnection structure 340 of the bumpless chip package 300 can be directly formed on the supporting component 310, the chip 320 and the metal-filled layer 330.

To sum up, the bumpless chip package and the fabricating process thereof according to the present invention have the following advantages:

(a) Since the material of the metal-filled layer filled between the chip and the cavity according to the present invention is metal, the metal-filled layer can increase the thermal conductive efficiency between the chip and the supporting component;

(b) Since the metal-filled layer of the present invention can be filled and formed between the chip and the cavity by electroplating, sputtering or metal deposition and so on, the metal-filled layer is more easily filled between the chin and the cavity compared with the conventional technology;

(c) Since the coefficient of thermal expansion of the metal-filled layer according to the present invention is similar to the coefficients of thermal expansion of the chip and the supporting component, the mismatch between the thermal expansion of the metal-filled layer of the present invention and those of the chip and the supporting component can be reduced so as to decrease the remaining of the thermal stress.

Although the present invention is disclosed as above by preferred embodiments, they are not intended to limit the present invention. Various variations and modifications can be made by those skilled in the art without departing from the spirit and scope of the present invention, and the scope of the present invention shall be defined by the appended claims.

What is claimed is:

1. A bumpless chip package, comprising:
a supporting component, having a supporting surface and a cavity;
a chip, disposed within the cavity, wherein the chip has a plurality of chip pads formed on an active surface of the chip, and wherein the active surface is upward;
a metal-filled layer, filled in a space formed between the chip and the cavity; and
an interconnection structure, formed above the active surface of the chip and the supporting surface of the supporting component, wherein the interconnection structure includes an inner circuit and a plurality of contact pads, the contact pads are formed on a contact surface of the interconnection structure, and at least one of the chip pads is electrically connected with at least one of the contact pads by the inner circuit.

2. The bumpless chip package of claim 1 further comprising a patterned metal layer, formed on the active surface of the chip and the supporting surface of the supporting component, located below the interconnection structure, and exposing part of each of the chip pads.

3. The bumpless chip package of claim 2, wherein the patterned metal layer has a plurality of openings and a plurality of conductive parts, each of the conductive parts is disposed on a corresponding one of the chip pads and is located within a corresponding one of the openings, and each of the openings is located on a corresponding one of the chip pads to expose a corresponding one of the chip pads and a corresponding one of the conductive parts.

4. The bumpless chip package of claim 1, wherein the interconnection structure comprising:
a plurality of dielectric layers;
a plurality of conductive vias, running through the dielectric layers respectively, wherein at least one of the conductive vias is electrically connected with at least one of the chip pads; and
a plurality of circuit layers, formed alternately with the dielectric layers, wherein the circuit layers and the conductive vias form the inner circuit, and two of the circuit layers are electrically connected by at least one of the conductive vias.

5. The bumpless chip package of claim 1, wherein the supporting component is a thermal-spreading component.

6. The bumpless chip package of claim 1, wherein the material of the supporting component is metal.

7. The bumpless chip package of claim 1 further comprising a thermal-conductive adhesion layer, disposed between a back surface of the chip opposite to the active surface and a corresponding bottom surface of the cavity, wherein the chip is adhered within the cavity by the thermal-conductive adhesion layer.

8. The bumpless chip package of claim 7, wherein the material of the thermal-conductive adhesion layer is solder, metal or thermal-conductive paste.

9. The bumpless chip package of claim 1 further comprising a plurality of electrical contacts, respectively disposed on the contact pads.

10. The bumpless chip package of claim 9, wherein the electrical contacts are conductive balls, conductive pins or conductive columns.

11. The bumpless chip package of claim 1, further comprising a solder mask layer, formed on the contact surface of the interconnection structure, and exposing each of the contact pads.

12. A fabricating process of bumpless chip package, comprising:
providing a supporting component, wherein the supporting component has a supporting surface and a cavity;
providing a chip, wherein the chip has a plurality of chip pads formed on an active surface of the chip;
disposing the chip within the cavity, such that the active surface is upward;
forming a metal-filled layer in a space formed between at least one side of the chip and at least one corresponding side wall of the cavity; and
forming an interconnection structure above the active surface of the chip and the supporting surface of the supporting component, wherein the interconnection structure has an inner circuit and a plurality of contact pads, the contact pads are formed on a contact surface of the interconnection structure, and at least one of the chip pads is electrically connected with at least one of the contact pads by the inner circuit.

13. The fabricating process of bumpless chip package of claim 12, before the step of forming the interconnection structure, further comprising forming a patterned metal layer on the active surface of the chip and the supporting surface of the supporting component, wherein the patterned metal layer exposes part of each of the chip pads.

14. The fabricating process of bumpless chip package of claim 13, wherein the patterned metal layer has a plurality of openings and a plurality of conductive parts, each of the conductive parts is disposed on a corresponding one of the chip pads and is located within a corresponding one of the openings, and each of the openings exposes a corresponding one of the corresponding chip pads and is used for the electronic insulation from each of the corresponding conductive parts.

15. The fabricating process of bumpless chip package of claim 12, wherein the step of forming the interconnection structure comprises:
forming a dielectric layer on the chip and the supporting part, wherein the dielectric layer exposes exposing each of the chip pads;
forming at least one conductive via to run through the dielectric layer, wherein the conductive via is electrically connected with one of the chip pads; and
forming a circuit layer and the contact pads on the dielectric layer, wherein the conductive via is electrically connected with the circuit layer or one of the contact pads, and the conductive via and the circuit layer form the inner circuit.

16. The fabricating process of bumpless chip package of claim 12, wherein the step of forming the interconnection structure comprises:
forming a first dielectric layer on the chip and the supporting part, and exposing each of the chip pads;
forming at least one first conductive via to run through the first dielectric layer, wherein the first conductive via is electrically connected with one of the chip pads;
forming a first circuit layer on the first dielectric layer to electrically connect the first conductive via;
forming a second dielectric layer on the first circuit layer;
forming at least a second conductive via to run through the second dielectric layer, wherein the second conductive via is electrically connected with the first circuit layer; and
forming a second circuit layer and the contact pads on the second dielectric layer, wherein the second conductive via is electrically connected with the second circuit layer or one of the contact pads, and wherein the first conductive via, the first circuit layer, the second conductive via and the second circuit layer form the inner circuit.

17. The fabricating process of bumpless chip package of claim 12, wherein a back surface of the chip opposite to the active surface is correspondingly adhered onto a bottom surface of the cavity by a thermal-conductive adhesion layer.

18. The fabricating process of bumpless chip package of claim 12, further comprising forming a plurality of electrical contacts on the contact pads respectively.

19. The fabricating process of bumpless chip package of claim 18, wherein the electrical contacts are conductive balls, conductive pins or conductive columns.

20. The fabricating process of bumpless chip package of claim 12, further comprising forming a solder mask layer on the contact surface of the interconnection structure, wherein the solder mask exposes each of the contact pads.
